(19) United States
(12) Patent Application Publication
(10) Pub. No.: US 2024/0420988 A1
(43) Pub. Date: Dec. 19, 2024

(54) SEMICONDUCTOR DEVICE ARRANGEMENT AND METHOD OF MANUFACTURING THE SAME

(71) Applicant: EPISTAR CORPORATION, Hsinchu (TW)

(72) Inventors: Chien-Chih CHEN, Hsinchu (TW); Wei-Shan HU, Hsinchu City (TW); Ching-Tai CHENG, Hsinchu (TW)

(21) Appl. No.: 18/740,907

(22) Filed: Jun. 12, 2024

(30) Foreign Application Priority Data
Jun. 13, 2023 (TW) 112121987

(51) Int. Cl. H01L 21/683; B32B 3/26; B32B 3/30; B32B 7/14; B32B 37/12; H01L 33/00

(52) U.S. Cl. CPC H01L 21/6835; B32B 3/263; B32B 3/30; B32B 7/14; B32B 37/1292; H01L 33/0093; B32B 2457/14; H01L 2221/68354; H01L 2221/68368

(57) ABSTRACT

An embodiment of the present disclosure provides a semiconductor device arrangement. This semiconductor device arrangement includes a carrier, a first semiconductor device, a second semiconductor device, a first adhesive portion, and a second adhesive portion. The first semiconductor device and the second semiconductor device are separately arranged on the carrier. The first adhesive portion and the second adhesive portion are separately arranged on the carrier, the first adhesive portion is located between the first semiconductor device and the carrier, and the second adhesive portion is located between the second semiconductor device and the carrier. In the cross-sectional view, the first adhesive portion includes an inclined sidewall, and the inclined sidewall is adjacent to the carrier and forms an interior angle greater than 90 degrees to the carrier.

This application claims priority to the benefit of TW Patent Application Number 112121987 filed on Jun. 13, 2023 and the entire content of which is hereby incorporated by reference herein in its entirety.

### TECHNICAL FIELD

The present disclosure relates to a semiconductor device arrangement, and more particularly, to a semiconductor device arrangement attached to a carrier and a method of manufacturing the same.

### DESCRIPTION OF BACKGROUND ART

A light-emitting diode (LED) is an optoelectronic semiconductor device that is suitable for diverse lighting and display applications because it has good characteristics, such as low power consumption, low heat generation, long operation life, shock tolerance, a compact size, and swift response.

In order to make different electronic equipment, a large number of LEDs need to be transferred between different substrates, and the steps usually include transferring a plurality of LEDs from a growth substrate to a temporary substrate, and fixing a plurality of LEDs on it through the adhesive layer on the temporary substrate. The etching process is then used to remove the adhesive layer between adjacent LEDs.

However, in the etching process, in order to remove the adhesive layer between adjacent LEDs completely, the etching process often takes a long time, and the heat generated by the etching process could cause some LEDs to be skewed in the vertical direction or offset in the horizontal direction. This not only makes the manufacturing process time-consuming, but is also detrimental to the continuous processing process.

### SUMMARY OF THE APPLICATION

According to one embodiment of the present disclosure, a semiconductor device arrangement is provided. This semiconductor device arrangement includes a carrier, a first semiconductor device, a second semiconductor device, a first adhesive portion, and a second adhesive portion. The first semiconductor device and the second semiconductor device are separately arranged on the carrier. The first adhesive portion and the second adhesive portion are separately arranged on the carrier, the first adhesive portion is located between the first semiconductor device and the carrier, and the second adhesive portion is located between the second semiconductor device and the carrier. Wherein, in a cross-sectional view, the first adhesive portion includes an inclined sidewall, and the inclined sidewall is adjacent to the carrier and forms an interior angle greater than 90 degrees to the carrier.

According to another embodiment of the present disclosure, a method of manufacturing a semiconductor device arrangement is provided. This method includes providing a first supporting substrate, a first semiconductor device, and a second semiconductor device, wherein the first semiconductor device and the second semiconductor device are located on the first supporting substrate and separated from each other; providing a patternable adhesive layer to cover the first semiconductor device, the second semiconductor device, and a space between the first semiconductor device and the second semiconductor device; removing the patternable adhesive layer located in the space by a photolithographic process to form a first adhesive portion and a second adhesive portion; and providing a second supporting substrate and contacting the first adhesive portion and the second adhesive portion to the second supporting substrate. The first adhesive portion is located between the first semiconductor device and the second supporting substrate and the second adhesive portion is located between the second semiconductor device and the second supporting substrate.

### BRIEF DESCRIPTION OF THE DRAWINGS

The embodiments of the present disclosure may be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1 illustrates a top view and a partial enlarged view of a semiconductor device arrangement in accordance with one embodiment of the present disclosure.

FIG. 2 illustrates is cross-sectional views taken along line A-A′ and line B-B′ of FIG. 1 in accordance with one embodiment of the present disclosure.

FIG. 3 illustrates two partial enlarged views of the cross-sectional views in FIG. 2 in accordance with one embodiment of the present disclosure.

FIG. 4 illustrates is a partial enlarged view of the cross-sectional view taken along line A-A′ in FIG. 2 in accordance with one embodiment of the present disclosure.

FIG. 5 illustrates a cross-sectional view and partial enlarged view taken along line A-A′ in FIG. 1 in accordance with one variant embodiment of the present disclosure.

FIG. 6 illustrates top views of some semiconductor device arrangements in accordance with some embodiments of the present disclosure.

FIG. 7 illustrates a top view and a partial enlarged view of providing multiple semiconductor devices on a first supporting substrate in accordance with one embodiment of the present disclosure.

FIG. 8 illustrates cross-sectional views of different steps of forming adhesive portions on semiconductor devices in accordance with one embodiment of the present disclosure.

FIG. 9 illustrates cross-sectional views of different steps of transferring multiple semiconductor devices from a supporting substrate to a carrier in accordance with one embodiment of the present disclosure.

FIG. 10 illustrates cross-sectional views of different steps of transferring selected semiconductor devices from a carrier to a supporting substrate in accordance with one embodiment of the present disclosure.

### DETAILED DESCRIPTION OF THE APPLICATION

The semiconductor device arrangements and manufacturing methods thereof in accordance with the embodiments of the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

For example, in the following description, forming a first component over or above a second component may include an embodiment that the first component and the second component are formed in direct contact, and may also include an embodiment that additional components may be formed between the first component and the second component such that the first component and the second component are not in direct contact.

In addition, for convenience of description, spatially relative terms such as “below”, “under”, “lower”, “upper”, “on”, and the like may be used herein to describe relationship of one component or element to another (or other) component or element as shown in the figures. Spatially relative terms are intended to comprise different orientations of the apparatus in use or operation in addition to the orientations shown in the figures. The device may be otherwise oriented (rotated 90 degrees or in other orientations) and the spatially relative descriptions used herein may be interpreted accordingly.

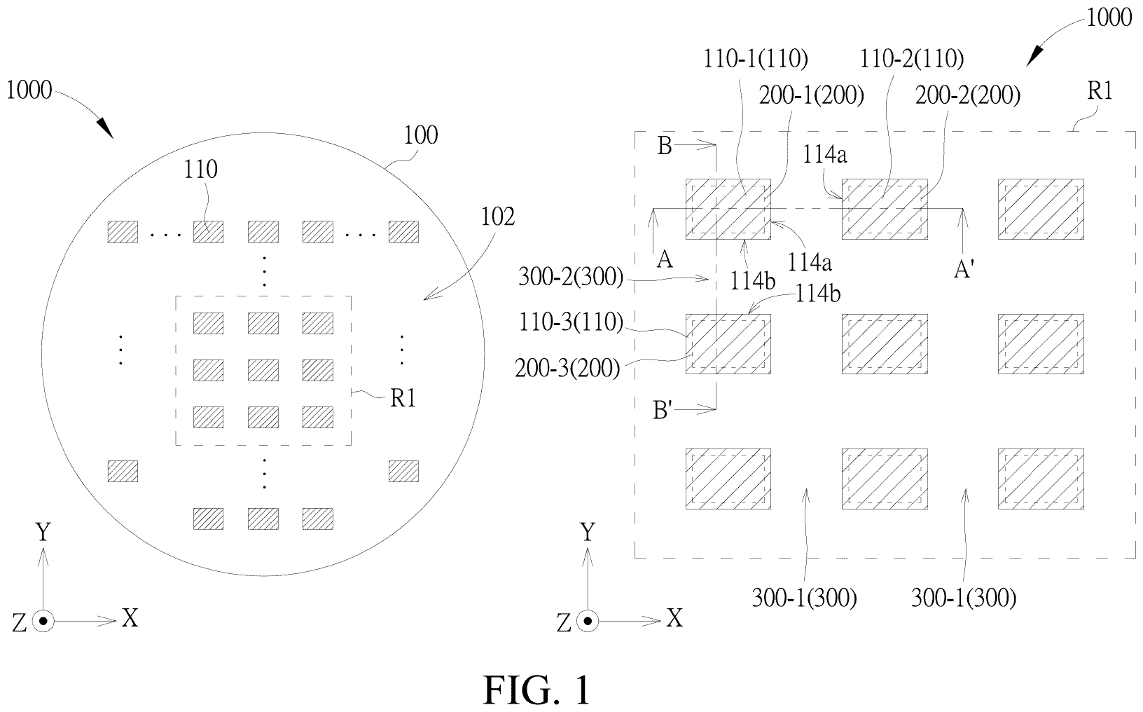

FIG. 1 is a top view and a partial enlarged view of a semiconductor device arrangement according to one embodiment of the present disclosure. As shown in FIG. 1, the semiconductor device arrangement 1000 includes a carrier 100, a plurality of semiconductor devices 110, and an adhesive layer 200 composed of a plurality of adhesive portions. A plurality of semiconductor devices 110 may present a specific arrangement structure and be located on the carrier 100 separately. Each adhesive portion is separated from one another and is arranged between the corresponding semiconductor device 110 and the carrier 100.

As shown in the top view on the left side of FIG. 1, the semiconductor device 110 and the corresponding adhesive portion (not shown) are arranged on an upper surface 102 of the carrier 100. According to one embodiment of this disclosure, the carrier 100 is used to support the semiconductor devices 110 on the upper surface 102 thereof, so the carrier 100 is also called a supporting substrate. According to one embodiment of the present disclosure, the carrier 100 may be a non-epitaxial material or a non-growth substrate, such as a ceramic substrate, a metal substrate, a glass substrate, a thermal release tape, an UV release tape, a chemical release tape, a heat-resistant tape, a blue tape, or a tape with a dynamic release layer. According to an embodiment of this disclosure, the carrier 100 may be a glass substrate, a sapphire substrate, or a quartz substrate. The carrier 100 is a substrate that allows laser light to penetrate so that the semiconductor device 110 may be separated from the carrier 100 by a laser lift-off (LLO) process. According to an embodiment, when the laser lift-off process is carried out, the laser light may be incident from the back of the carrier 100 into the carrier 100 and penetrate through the upper surface 102 of the carrier 100. The laser light irradiates to the adhesion portions arranged on the upper surface 102 to partially or completely decompose or vaporize the corresponding adhesive portions such that the semiconductor devices can be peeled off from the carrier 100. In addition, the carrier 100 is electrically insulated from semiconductor device 110, so that the electric signals are not transmitted between the carrier 100 and semiconductor devices 110.

Semiconductor devices 110 may include transistors or semiconductor light-emitting devices, such as light-emitting diode devices. The adjacent semiconductor devices 110 are separated from each other. For the adjacent semiconductor devices 110 in the same column or row, the minimum distance between the adjacent semiconductor devices 110 is 1 μm to 50 μm. According to one embodiment, in a top view, the minimum distance between adjacent semiconductor devices 110 is less than the diagonal length of each semiconductor device 110. For example, the distance between adjacent semiconductor devices 110 is 1/20 to ⅕ of the diagonal length of each semiconductor device 110. A plurality of semiconductor devices 110 forms a specific arrangement, such as an array structure on a carrier 100. According to an embodiment, a plurality of semiconductor devices 110 forms a plurality of ring-like structures and are concentric with one another.

For the region R1 of the left top view in FIG. 1, the enlarged view thereof is shown in the right top view in FIG. 1. As shown in the top view on the right side in FIG. 1, in the region R1, the semiconductor devices 110 forms an array of 3 rows and 3 columns, and there are gaps 300 between the adjacent rows and between the adjacent columns, such as the first gap 300-1 and the second gap 300-2. According to an embodiment, each first gap 300-1 extends along a first direction (e.g., Y direction) so that the adjacent rows of the semiconductor devices 110 are separated by the first gap 300-1, and each second gap 300-2 extends in a second direction (e.g., X direction) different from the first direction so that the adjacent columns of the semiconductor devices 110 are separated by the second gap 300-2. In addition, in the top view, the first gap 300-1 and the second gap 300-2 are located between the adjacent adhesive portions of the adhesive layer 200 to expose the upper surface 102 of the carrier 100.

Semiconductor devices 110 include a first semiconductor device 110-1, a second semiconductor device 110-2, a third semiconductor device 110-3 . . . and a m^{th} semiconductor device, and m is a positive integer greater than 3. The first semiconductor device 110-1 and the second semiconductor device 110-2 are located in the same column and arranged in the X direction, and the first semiconductor device 110-1 and the third semiconductor device 110-3 are located in the same row and arranged in the Y direction. According to an embodiment, each semiconductor device 110 (e.g., a first semiconductor device 110-1, a second semiconductor device 110-2, and a third semiconductor device 110-3) includes a plurality of outermost sidewalls, such as the parallel first outermost sidewall 114a and second outermost sidewall 114b, and the first outermost sidewall 114a is adjacent to the second outermost sidewall 114b. According to an embodiment, each semiconductor device 110 has a projection area in the Z direction, and this projection area is 50 μm² to 5000 μm².

As shown in the top view on the right side of FIG. 1, the adhesive layer 200 includes a plurality of adhesive portions which are separated from each other and are used to connect the corresponding semiconductor devices 110 to the carrier 100. According to an embodiment, each adhesive portion of the adhesive layer 200 is fully covered by (or called completely overlapped with) the corresponding semiconductor device 110 in the top view, so that the outermost sidewall of one adhesive portion of the adhesive layer 200 does not exceed the outermost sidewall of the semiconductor device 110 (e.g., the first outermost sidewall 114a and the second outermost sidewall 114b). According to an embodiment, each adhesive portion of the adhesive layer 200 has a projection area in the Z direction, for example, 40 μm² to 4000 μm², and this projection area is smaller than the projection area of the corresponding semiconductor device 110 in the Z direction. According to an embodiment, the adhesive portion of the adhesive layer 200 includes a patterned photoresist layer, and its profile in the top view and bottom surface area can be defined by a photolithographic process. Therefore, the distance between the outermost sidewall of the corresponding adhesive portion of the adhesive layer 200 and the outermost sidewall of the semiconductor device 110 in the top view can be adjusted according to different needs.

A plurality of adhesive portions of the adhesive layer 200 constitutes a specific arrangement, and its arrangement corresponds to the arrangement composed of a plurality of semiconductor devices 110. According to an embodiment, a plurality of adhesive portions of the adhesive layer 200 may constitute an array structure or a ring structure. The adhesive layer 200 include a first adhesive portion 200-1, a second adhesive portion 200-2, a third adhesive portion 200-3 . . . and a m^{th} adhesive portion, and wherein m is a positive integer greater than 3. The first adhesive portion 200-1 and the second adhesive portion 200-2 are located in the same column and arranged in the X direction, and the first adhesive portion 200-1 and the third adhesive portion 200-3 are located in the same row and arranged in the Y direction.

The adhesive layer 200 can be a polymer, and according to different embodiments, the adhesive layer 200 includes polyimide (PI), epoxy resin (EPO), polybenzoxazole (PBO), polysiloxane, cyclic olefin polymer (COP), or benzocyclobutane (BCB).

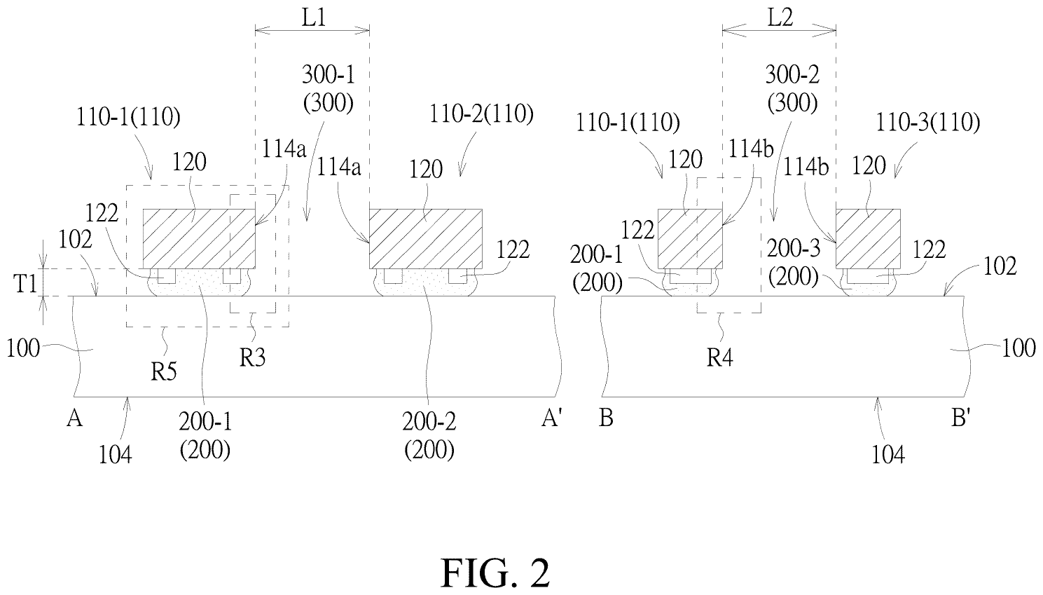

FIG. 2 is cross-sectional views along line A-A′ and line B-B′ in FIG. 1. Regarding the cross-sectional view along line A-A′, carrier 100 includes an upper surface 102 and a lower surface 104 opposite to each other. The first gap 300-1 is located between the first semiconductor device 110-1 and the second semiconductor device 110-2 and exposes the upper surface 102 of the carrier 100. The first outermost sidewall 114a of the first semiconductor device 110-1 faces the first outermost sidewall 114a of the second semiconductor device 110-2, and the minimum distance L1 between the corresponding first outermost sidewalls 114a is 1 μm to 50 μm. According to an embodiment, the first semiconductor device 110-1 and the second semiconductor device 110-2 have the same or similar structures. Each semiconductor device 110 includes a main body 120 and at least one electrode 122, such as a pair of electrodes 122. The main body 120 includes a semiconductor stack for the flow of electrons or holes (not shown). The electrodes 122 face the upper surface 102 of the carrier 100, so that the electrodes 122 and the adhesive portions are on the same side of the main bodies 120, and the electrodes 122 and the carrier 100 are separated by the adhesive layer 200. The electrode 122 may contain a single layer or multiple layers of metal, and the electrode 122 includes one material selected from the group composed of chromium (Cr), nickel (Ni), titanium (Ti), platinum (Pt), palladium (Pd), silver (Ag), gold (Au), aluminum (Al), and copper (Cu).

The structure of each semiconductor device 110 is not limited to the structure shown in the FIG. 2. According to an embodiment, each semiconductor device 110 includes a redistribution layer (RDL) (not shown), which is arranged under the lower surface of the main body 120. The redistribution layer includes the interconnect(s), the via(s), and the bonding pad(s). Bonding pads have a specific layout, and in the subsequent process, the bonding pads may be electrically connected to external circuits. In addition, according to an embodiment, each semiconductor device 110 may include a fan-out package structure, so that the main body 120 includes one semiconductor chip and a molding material surrounding the chip.

The adhesive layer 200 is located between the semiconductor device 110 and the carrier 100. For example, the first adhesive portion 200-1 is located between the first semiconductor device 110-1 and the carrier 100, and the second adhesive portion 200-2 is located between the second semiconductor device 110-2 and the carrier 100. According to one embodiment, the maximum thickness T1 of the adhesive layer 200 is 2 μm to 7 μm. When the maximum thickness T1 is less than 2 μm, the adhesion between the semiconductor device 110 and the carrier 100 may be insufficient, and when the thickness T1 of the adhesive layer 200 is greater than 7 μm, the cross-sectional profile of each adhesive portion of the adhesive layer 200 may deviate from the predetermined profile (especially for the adhesive portion obtained by the photolithographic process).

Regarding the cross-sectional view along line B-B′, the second gap 300-2 is located between the first semiconductor device 110-1 and the third semiconductor device 110-3, and exposes the upper surface 102 of the carrier 100. The second outermost sidewalls 114b of the first semiconductor device 110-1 and the third semiconductor device 110-3 face each other, and the minimum distance L2 between the corresponding second outermost sidewalls 114b is 1 μm to 50 μm. According to an embodiment, the first semiconductor device 110-1 and the third semiconductor device 110-3 have the same or similar structures. Each semiconductor device 110 includes a main body 120 and at least one electrode 122. According to an embodiment, the electrode 122 faces the upper surface 102 of the carrier 100, so that the electrode 122 and the corresponding adhesive portion are on the same side of the main body 120, and the electrode 122 and the carrier 100 are separated by the adhesive layer 200.

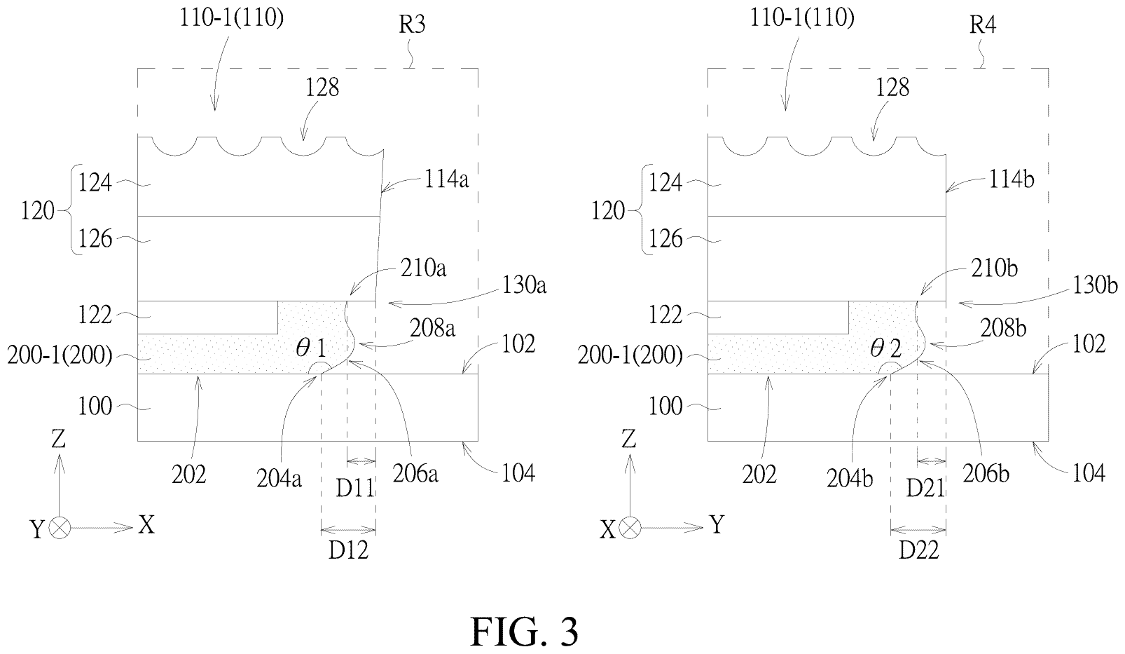

FIG. 3 is an enlarged view of a region in FIG. 2 according to one embodiment in the present disclosure, wherein the left cross-sectional view in FIG. 3 corresponds to the region R3 in FIG. 2, and the right cross-sectional view in FIG. 3 corresponds to the region R4 in FIG. 2. As shown in the left cross-sectional, according to an embodiment, the first semiconductor device 110-1 and the remaining semiconductor devices 110 are semiconductor light-emitting devices, and the main body 120 of the first semiconductor device 110-1 includes a substrate 124 and a semiconductor stack 126. The semiconductor stack 126 is arranged between the electrode 122 and the substrate 124, and is electrically connected to the electrode 122. According to an embodiment, the semiconductor stack 126 includes a first semiconductor layer (not shown), a light-emitting layer (not shown), and a second semiconductor layer (not shown), wherein the first semiconductor layer and the second semiconductor layer respectively include dopants of different conductive forms, such as n-type dopants and p-type dopants, so that the first semiconductor layer and the second semiconductor layer can supply electrons and electric holes respectively.

According to an embodiment, the substrate 124 includes a plurality of depression areas 128 far away from the carrier 100. The diameter of each depression area 128 is 1 μm to 4 μm and the depth thereof is 300 nm to 2 μm. The depression areas 128 have repetitive shapes and are distributed on the main surface of the substrate 124 (along the X-Y plane). By forming the depression areas 128, the luminous efficiency of the semiconductor device 110 (e.g., the first semiconductor device 110-1) can be increased or the contour of the light distribution curve thereof can be adjusted.

According to an embodiment, the first adhesive portion 200-1 includes an inclined sidewall 206a. The inclined sidewall 206a is adjacent to the carrier 100 and forms an internal angle θ1 greater than 90 degrees with the upper surface 102. The slope of the tangent of each point on the inclined sidewall 206a can be approximately a fixed value, or it can be gradually increased in the direction (Z direction) away from the carrier 100. According to an embodiment, the first adhesive portion 200-1 further includes a lower surface 202 contacting the carrier 100, and the lower surface 202 contacts the upper surface 102 of the carrier 100.

According to an embodiment, in the cross-sectional view, the first adhesive portion 200-1 also includes a bottom portion 204a, a protruding portion 208a and a top portion 210a, and the protruding portion 208a is located between the top portion 210a and the internal bottom portion 204a. Because the lateral profile of the first adhesive portion 200-1 is not a vertical line, the projection distances from the bottom portion 204a, the protruding portion 208a. and the top portion 210a to the bottom portion 130a of the first outermost sidewall 114a on the upper surface 102 of the carrier 100 (along the X-Y plane) are different. For example, there is a first projection distance D11 between the top portion 210a of the first adhesive portion 200-1 and the bottom portion 130a of the first outermost sidewall 114a, there is a second projection distance D12 between the bottom portion 204a of the first adhesive portion 200-1 and the bottom portion 130a of the first outermost sidewall 114a, and the first projection distance D11 is smaller than the second projection distance D12.

As shown in the right cross-sectional view of FIG. 3, according to an embodiment, the substrate 124 includes a plurality of depression areas 128 far away from the carrier 100. The depression areas 128 have repetitive shapes and are distributed on the main surface of the substrate 124 (along the X-Y plane). According to one embodiment, the crystal plane of the second outermost sidewall 114b is different from the crystal plane of the first outermost sidewall 114a, so the slopes of the crystal planes thereof are different. According to an embodiment, the second outermost sidewall 114b is a vertical plane, and its slope can be greater than the slope of the first outermost sidewall 114a.

According to an embodiment, the first adhesive portion 200-1 includes an inclined sidewall 206b. The inclined sidewall 206b is adjacent to the carrier 100 and forms an internal angle θ2 greater than 90 degrees with the upper surface 102. The slope of the tangent of each point on the inclined sidewall 206b is approximately a fixed value or gradually increased in the direction (Z direction) away from the carrier 100.

According to an embodiment, in the cross-sectional view, the first adhesive portion 200-1 also includes a bottom portion 204b, a protruding portion 208b, and a top portion 210b, and the protruding portion 208b is located between the top portion 210b and the bottom portion 204b. Because the lateral profile of the first adhesive portion 200-1 is not a vertical line, the projection distances form the bottom portion 204b, the protruding portion 208b, and the top portion 210b to the bottom portion 130b of the second outermost sidewall 114b on the upper surface 102 of the carrier 100 (along the X-Y plane) are different. For example, there is a first projection distance D21 between the top portion 210b of the first adhesive portion 200-1 and the bottom portion 130b of the second outermost sidewall 114b, there is a second projection distance D22 between the bottom portion 204b of the first adhesive portion 200-1 and the bottom portion 130b of the second outermost sidewall 114b, and the first projection distance D21 is smaller than the second projection distance D22.

According to different requirements, the internal angle θ1 can be different from the internal angle θ2, and the first projection distance D11 and the second projection distance D12 can be different from the first projection distance D21 and the second projection distance D22, respectively.

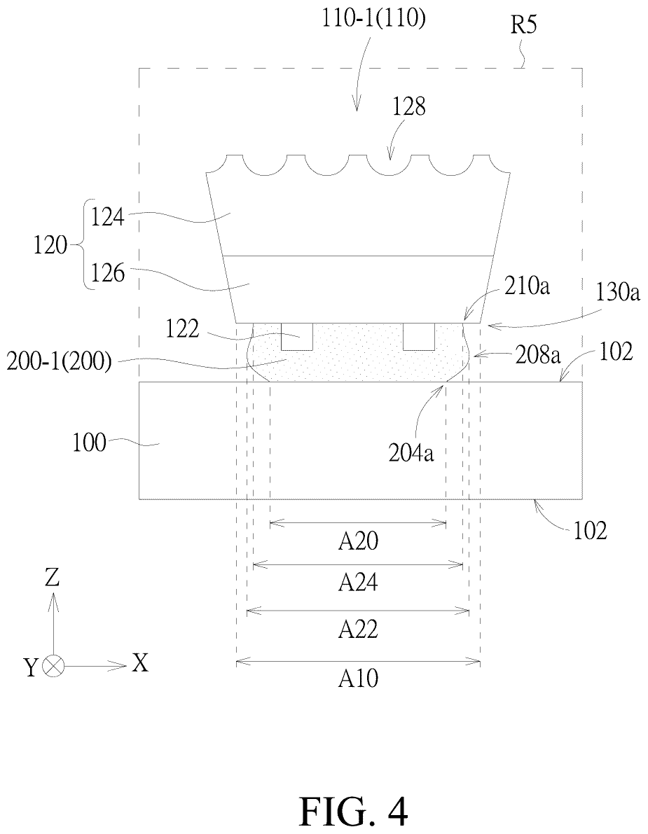

FIG. 4 is a partial enlarged view of region R5 in FIG. 2. As shown in FIG. 4, in the cross-sectional view, the bottom portion 204a, the protruding portion 208a, and the top portion 210a of each adhesive portion of the adhesive layer 200 (e.g., first adhesive portion 200-1) are arranged correspondingly. The bottom surface of the first semiconductor device 110-1 has a first projection area A10, the bottom surface 202 of the first adhesive portion 200-1 has a second projection area A20, the transverse section of the protruding portion 208a of the first adhesive portion 200-1 has a third projection area A22, and the transverse section of the top portion 210a of the first adhesive portion 200-1 has a fourth projection area A24. According to an embodiment, the second projection area A20 of the bottom surface 202 of the first adhesive portion 200-1 is smaller than the first projection area A10 of the first semiconductor device 110-1. According to an embodiment, the projection areas in the order from small to large are the second projection area A20 of the first adhesive portion 200-1, the fourth projection area A24 of the first adhesive portion 200-1, the third projection area A22 of the first adhesive portion 200-1, and the first projection area A10 of the first semiconductor device 110-1.

Referring to both FIGS. 3 and 4, according to an embodiment, at least one of the interior angles θ1 and θ2 of the adhesive portion of the adhesive layer 200 is greater than 90 degrees, and the contact area between the bottom surface 202 of the adhesive portion and the carrier 100 (upper surface 102) can be reduced. Because the contact area between the bottom surface 202 of the adhesive portion 200 and the carrier 100 (the second projection area A20) can be adjusted in advance through the photolithographic process in accordance with the light spot shape of the laser light, the bottom surface 202 of the adhesive portion can be detached from the carrier 100 easily during the subsequent laser ablating process. In addition, as shown in FIG. 3, compared with the top portions 210a, 210b and the bottom portions 204a, 204b, the protruding portions 208a, 208b are closer to the outermost sidewalls of the semiconductor sidewalls 110, respectively (e.g., the first outermost sidewall 114a and the second outermost sidewall 114b), so that the laser light irradiated from the lower surface 104 of the carrier 100 to the semiconductor devices 110 can be partially or wholly absorbed by the adhesive layer 200. The semiconductor devices 110 are prevented from being damaged by directly irradiated by the laser light.

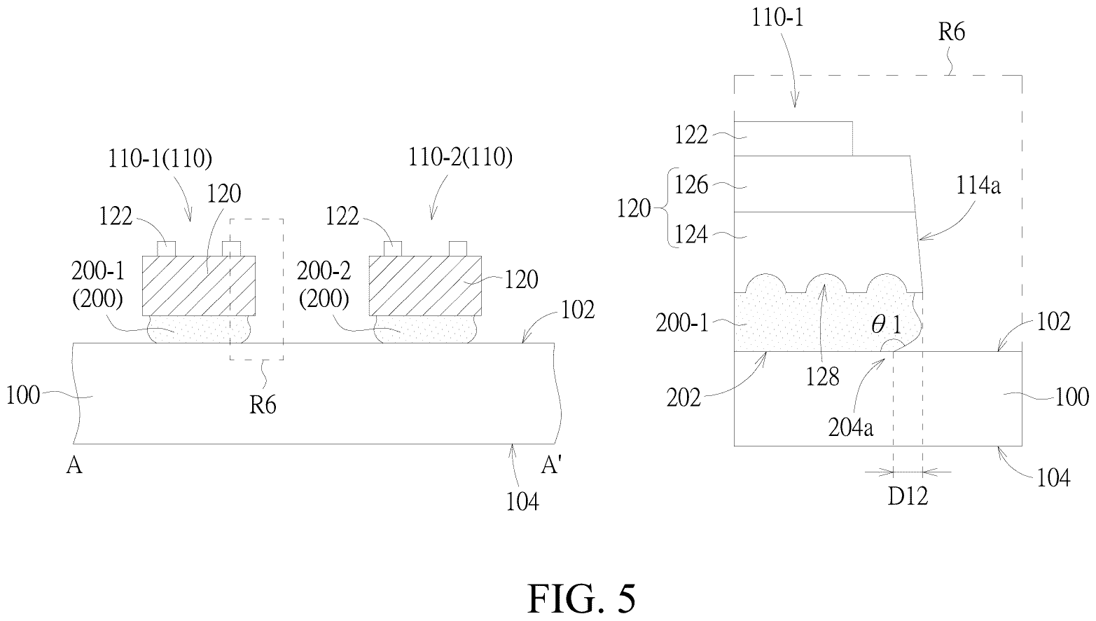

FIG. 5 is a cross-sectional view taken along line A-A′ in FIG. 1 according to one variation embodiment of the present disclosure. As shown in the left cross-sectional view of FIG. 5, which is similar to the left cross-sectional view of FIG. 2, the main difference between the two is that the electrodes 122 of the first semiconductor device 110-1 and the second semiconductor device 110-2 are far away from the carrier 100 instead of facing the carrier 100. The first adhesive portion 200-1 is located between the first semiconductor device 110-1 and the carrier 100, and the second adhesive portion 200-2 is located between the second semiconductor device 110-2 and the carrier 100.

For the region R6 of the left cross-sectional view in FIG. 5, the enlarged view thereof is shown as the right cross-sectional view in FIG. 5. As shown in the cross-sectional view on the right side of FIG. 5, which is similar to the cross-sectional view on the left side of FIG. 3, with the main difference therebetween is that the depression areas 128 of the substrate 124 of the first semiconductor devices 110-1 face the carrier 100 instead of being far away from the carrier 100. The first adhesive portion 200-1 fills in or fully fills each depression area 128, so that the adhesion between the first semiconductor device 110-1 and the carrier 100 can be increased without changing the material or overall thickness of the first adhesive portion 200-1.

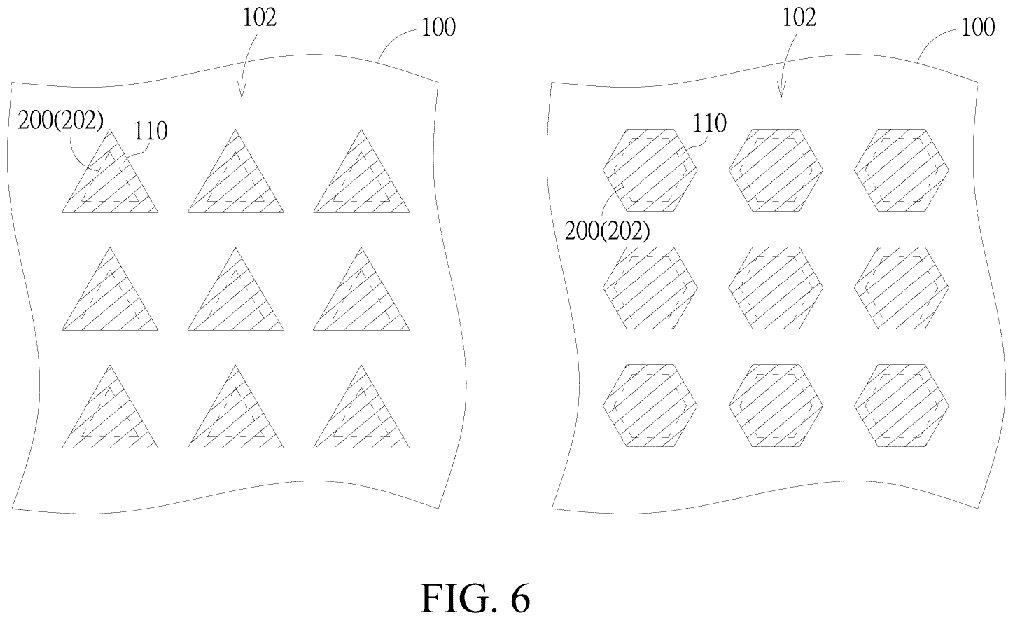

FIG. 6 illustrates top views of the semiconductor device arrangements according to some embodiments of the present disclosure. As shown in FIG. 6, the left top view and the right top view correspond to regions R1 of FIG. 1, respectively, and the main difference is that the top view profile of the semiconductor devices 110 located on the upper surface 102 of the carrier 100 is not rectangular, but triangular or hexagonal. Depending on the actual requirements, the top view profile of the semiconductor device 110 can be polygon or other geometric shape. The adhesive layer 200 fully covers the semiconductor element 110, and the outermost sidewall of the corresponding adhesive portion is separated from the outermost sidewall of the semiconductor device 110. According to an embodiment, the outermost sidewall of the corresponding adhesive portion of the adhesive layer 200 and the outermost sidewall of the semiconductor device 110 are coplanar.

In order to enable those who have ordinary skill in the field of the art to realize the present disclosure, the following further describes the manufacturing method of making the semiconductor device arrangement.

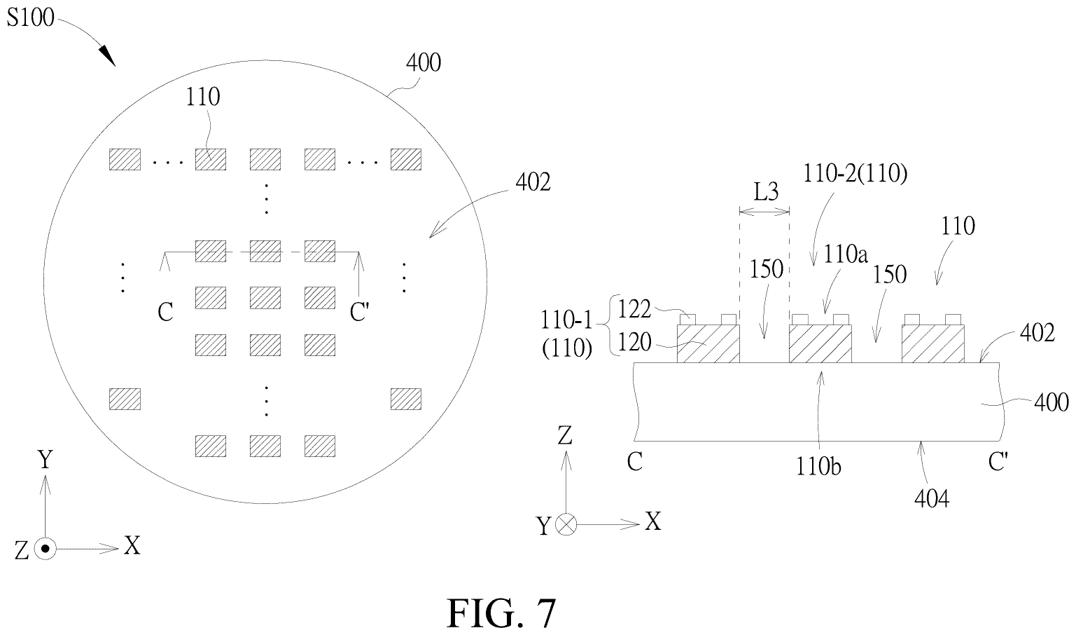

FIG. 7 is a top view of a manufacturing step to arrange a plurality of semiconductor devices on a first supporting substrate according to one embodiment of the present disclosure. As shown in FIG. 7, in step S100, a first supporting substrate 400 and a plurality of semiconductor devices 110 are provided, and the semiconductor devices 110 are arranged on the upper surface 402 of the first supporting substrate 400. According to one embodiment, the first supporting substrate 400 is a growth substrate, and the semiconductor devices 110 grow on the growth substrate. The growth substrate includes material such as silicon (Si), germanium (Ge), lithium aluminate (LiAlO₂), zinc oxide (ZnO), silicon carbide (SiC), sapphire, gallium nitride (GaN), aluminum nitride (AlN), gallium arsenide (GaAs), and phosphorus indium (InP).

The right side of FIG. 7 is an enlarged cross-sectional view of region C-C′ in the top view on the left side in FIG. 7. As shown in the figure, the adjacent semiconductor devices 110 are separated from each other, and there is a space 150 therebetween. According to an embodiment, the minimum distance L3 between adjacent semiconductor devices 110 (first semiconductor device 110-1 and second semiconductor device 110-2) is 1 μm to 50 μm, and the minimum distance L3 is less than the diagonal length of each semiconductor device 110 in a top view. For example, the minimum distance between adjacent semiconductor devices 110 is 1/20 to ⅕ of the diagonal length of each semiconductor device 110. A plurality of semiconductor devices 110 constitutes a specific arrangement, such as an array arrangement on the first supporting substrate 400. According to an embodiment, a plurality of semiconductor devices 110 forms a plurality of ring-like structures and are concentric with one another.

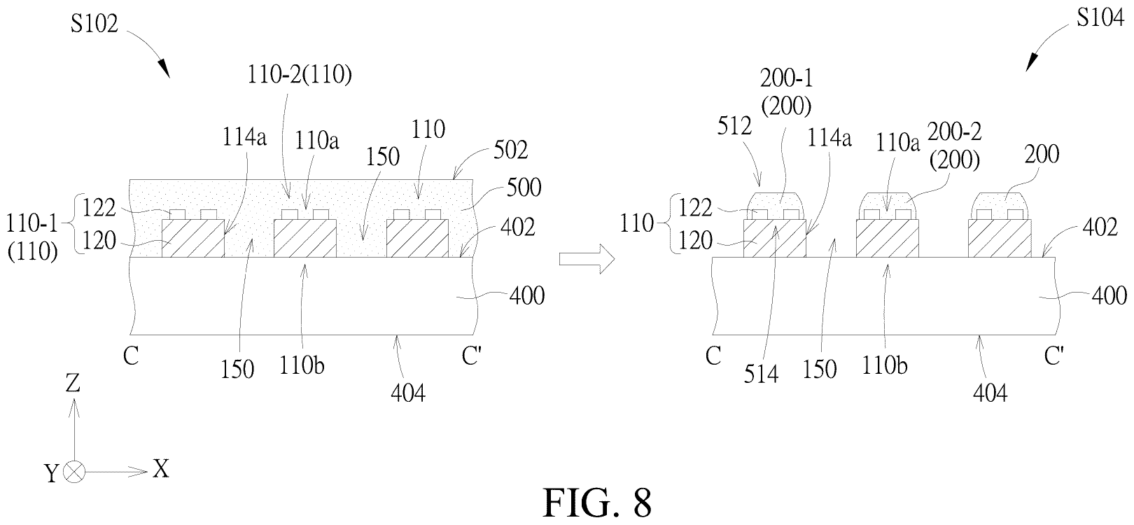

FIG. 8 is cross-sectional views of different manufacturing steps of forming adhesive portions on semiconductor devices in region C-C′ of the left top view in FIG. 7 in accordance with one embodiment of the present disclosure. In step S102, a patternable adhesive layer 500 is provided to cover the semiconductor devices 110 (first semiconductor device 110-1 and second semiconductor device 110-2) and to cover a space 150 located between the first semiconductor device 110-1 and the second semiconductor device 110-2. According to an embodiment, the semiconductor device 110 includes opposite upper surface 110a and lower surface 110b. The upper surface 502 of the patternable adhesive layer 500 is higher than the upper surface 110a of the semiconductor device 110 so that the patternable adhesive layer 500 fully covers the upper surface 110a of the semiconductor device 110 and fully fills the space 150 between the semiconductor devices 110.

According to an embodiment, the manufacturing method of forming the patternable adhesive layer 500 can be a spin coating method by coating the patternable adhesive material at a predetermined rotation speed (1000 rpm to 4000 rpm) and in a predetermined rotation stage(s) (1 stage fixed speed or 3 stages of different speeds) on the upper surface 402 of the first supporting substrate 400 so that the patternable adhesive material covers the semiconductor devices 110 and fills the space 150. Therefore, all the upper surface 402 of the first supporting substrate 400 is not exposed. By adjusting the rotation speed and rotation stage(s), it is possible to control the thickness of the patternable adhesive material. This is followed by a soft bake process to remove the solvent from the patternable adhesive material and to form a non-flowing patternable adhesive layer 500. According to an embodiment, the patternable adhesive layer 500 is a photoresist material with adhesiveness, and its composition may include a photosensitive substance (a functional group or a monomer), an adhesive substance (a functional group or a monomer), and a polymer matrix. The composition of photosensitive substances includes sulfonates, naphthoquinone diazide, diazoquinone, or other derivatives. The composition of adhesive substances includes epoxy resins or other crosslinkers. Polymer matrices include uncured polymers, such as cyclo olefin polymer (COP), polyimide (PI), epoxy resin (EPO), polybenzoxazole (PBO), polysiloxane, cyclic olefin polymer (COP), or benzocyclobutane (BCB). Since the patternable adhesive layer 500 contains adhesive functional groups or monomers in addition to photosensitive functional groups or monomers, even if the patternable adhesive layer 500 is subsequently patterned by a photolithographic process, the formed patterned adhesive layer still has appropriate adhesiveness (can be used as the adhesive layer 200). Alternatively, an additional activation process can cause the adhesive material in the patterned adhesive layer 500 to produce appropriate adhesiveness, so that the patterned adhesive layer 500 can be used to attach other components. As a result, this patterned photoresist layer with appropriate adhesiveness can be used to bond to the parts in the subsequent lamination process.

After completing step S102, step S104 is then executed to remove the patternable adhesive layer 500 located in space 105, to expose partial upper surface 402 of the first supporting substrate 400, and to form a patterned adhesive layer on top of the semiconductor devices 110, such as a plurality of adhesive portions (first adhesive portion 200-1 and second adhesive portion 200-2). According to an embodiment, the photolithographic process is used to remove the patternable adhesive layer 500 in the space 105, and the patternable adhesive layer 500 is patterned to produce a specific cross-sectional profile and a specific top profile. For example, the patternable adhesive layer 500 includes a positive photoresist, so the area where the patternable adhesive layer 500 is exposed to light can be removed. In addition, due to the developing property of the positive photoresist, the projection area of the upper surface 512 of each adhesive portion of the adhesive layer 200 is smaller than the projection area of the lower surface 514 of each adhesive portion of the adhesive layer 200.

According to an embodiment, each semiconductor device 110 includes a plurality of outermost sidewalls such as a first outermost sidewall 114a. After removing the patternable adhesive layer 500 in the space 105 to obtain the plurality of adhesive portions, more than 50% of the area of outermost sidewalls of the semiconductor devices 110 is not covered by the adhesive layer 200. In the embodiment, as shown in the figure, the outermost sidewall 114a of the semiconductor device 110 is not fully covered by the adhesive layer 200. In addition, in step S104, the upper surface 512 of each adhesive portion is higher than the upper surface 110a of each semiconductor device 110. Since the profile of the adhesive portions can be determined by the mask pattern used in the photolithographic process, the outermost sidewall of the adhesive portion can be avoided from being covered by the semiconductor device 110. Therefore, there is no need for an etching process to remove the adhesive portion between the adjacent semiconductor devices 110. Because the etching process is eliminated, the skew or offset of the semiconductor devices 110 caused by the heat from the etching process can be effectively avoided.

In step S104, the activation process can be further carried out to activate the adhesive substance remaining in the adhesive layer 200 so that the adhesive substance can produce more free radicals in the subsequent bonding process, and the strength between the adhesive layer 200 and the target component can be increased. In addition, during the activation process, the adhesive layer 200 does not undergo cross-linking reactions. According to one embodiment, the activation process includes a heat treatment in a gas environment. The gas composition in this gas environment is mainly nitrogen, and the oxygen concentration is low (e.g. less than 1000 ppm).

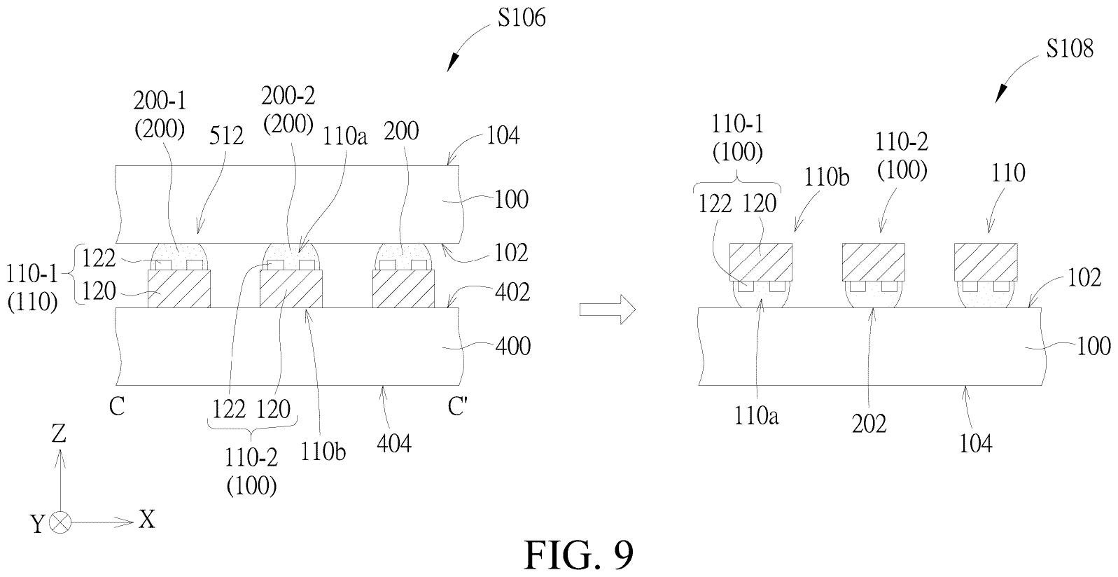

FIG. 9 is cross-sectional views of the manufacturing steps of transferring a plurality of semiconductor devices from the first supporting substrate to the carrier in region C-C′ of the left top view in FIG. 7 in accordance with one embodiment of the present disclosure. In step S106, the semiconductor devices 110 on the first supporting substrate 400 faces the carrier 100 (second supporting substrate). According to an embodiment, the carrier 100 has opposite upper surface 102 and lower surface 104, and the upper surface 110a of the semiconductor device 110 faces the upper surface 102 of the carrier 100.

In step S106, attach the first supporting substrate 400 to the carrier 100 so that the carrier 100 contacts the adhesive layer 200 (first adhesive portion 200-1 and second adhesive portion 200-2). In more detail, contact the upper surface 512 of the corresponding adhesive portion of the adhesive layer 200 to the upper surface 102 of the carrier 100 and make the adhesive layer 200 firmly connected to the carrier 100. Meanwhile, the first adhesive portion 200-1 is located between the first semiconductor device 110-1 and the carrier 100 (second supporting substrate), and the second adhesive portion 200-2 is located between the second semiconductor device 110-2 and the carrier 100. According to an embodiment, in order to make the adhesive layer 200 firmly connected to the carrier 100, a pressing process can be carried out to make the carrier 100 contact the adhesive layer 200. This is followed by a hard baking process which causes a cross-linking reaction between the cross-linker and the uncross-linked polymer in the adhesive layer 200. According to one embodiment, the process temperature to produce the cross-linking reaction is higher than that of the activation process used to activate the adhesive material, for example, 200° C. for the former and 100° C. for the latter.

In step S108, a separation process is carried out to separate the first supporting substrate 400 and the carrier 100, to separate the semiconductor devices 110 from the first supporting substrate 400, and to expose the lower surface 110b of the semiconductor device 110. According to an embodiment, a laser ablation process can be carried out to irradiate a laser light from the lower surface 404 of the first supporting substrate 400 to the upper surface 402 thereof such that the semiconductor material such as gallium nitride located between the semiconductor device 110 and the first supporting substrate 400 is dissociated. The semiconductor device 110 and the first supporting substrate 400 are separated by gas formed therebetween. After the separation process is completed, the semiconductor device 110 can be further cleaned to remove semiconductor residues or metal residues remaining on the lower surface 110b of the semiconductor device 110, such as gallium-containing particles. As a result, unnecessary electrical connections to the semiconductor devices 110 can be avoided. After completing step S108, a semiconductor device arrangement similar to that shown in FIG. 1 is obtained.

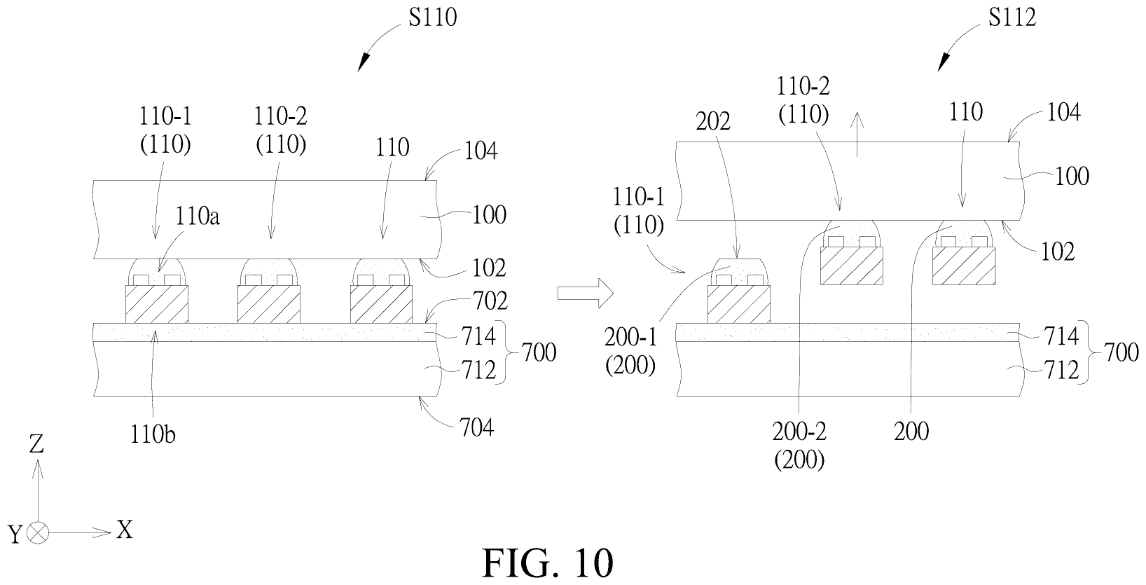

After forming the semiconductor device arrangement shown in step S108, the semiconductor devices 110 on the carrier 100 can be further transferred to other supporting substrates separately, so that the semiconductor devices 110 with similar or identical electrical properties or optical properties can be grouped, and the steps are similar with the steps shown in FIG. 10.

FIG. 10 is cross-sectional views of the different manufacturing steps of transferring semiconductor devices from a carrier to a third supporting substrate according to an embodiment of the present disclosure. In step S110, place the lower surfaces 110b of the semiconductor devices 110 on the carrier 100 to face the third supporting substrate 700. According to an embodiment, the third supporting substrate 700 has opposite upper surface 702 and lower surface 704. The upper surface 702 faces the carrier 100, and the lower surface 704 is far away from the carrier 100. The third supporting substrate 700 can be a non-epitaxial material or a non-growth substrate, such as a ceramic substrate, a metal substrate, a glass substrate, a thermal release tape, a UV release tape, a chemical release tape, a heat-resistant tape, a blue tape, or a tape with a dynamic release layer (DRL). According to an embodiment, the third supporting substrate 700 includes a carrier 712 and an attachment layer 714. The carrier 712 has sufficient mechanical strength to carry the attachment layer 714. The attachment layer 714 is sticky enough to fix the parts to which it is pressed. Then, while the upper surface 102 of the carrier 100 faces the upper surface 702 of the third supporting substrate 700, attach the carrier 100 to the third supporting substrate 700 so that the semiconductor devices 110 located on the carrier 100 contact the attachment layer 714 of the third supporting substrate 700.

In step S112, a separation process is carried out to transfer the selected semiconductor devices 110 (first semiconductor device 110-1) from the carrier 100 to the third supporting substrate 700, and to expose the lower surface 202 of the first adhesive portion 200-1. The remaining unselected semiconductor devices 110 (second semiconductor 110-2) are still on the upper surface 102 of the carrier 100. According to an embodiment, taking advantage of a laser ablation process, irradiate a laser light to the selected first semiconductor device 110-1 to decompose or vaporize the first adhesive layer 200-1 located between the first semiconductor device 110-1 and the carrier 100, so that the first semiconductor device 110 is separated from the carrier 100. For the unselected semiconductor devices 110 which are not irradiated by the laser light, they are still arranged on the upper surface 102 of the carrier 100. According to an embodiment, in the successive manufacturing process, other selected semiconductor devices 110 (second semiconductor components 110-2) may continue to be transferred from the carrier 100 to other support substrates (not shown), and the transferring process may be repeated until all the semiconductor devices 110 located on the carrier 100 are transferred to the selected same and/or different supporting substrates.

Although some embodiments of the present disclosure and their advantages have been described in detail, various changes, substitutions and alterations may be made herein without departing from the spirit and scope of the disclosure as defined by the appended claims.

What is claimed is:

1. A semiconductor device arrangement, comprising:
a carrier;
a first semiconductor device and a second semiconductor device, separately arranged on the carrier; and
a first adhesive portion and a second adhesive portion, separately arranged on the carrier, the first adhesive portion located between the first semiconductor device and the carrier, and the second adhesive portion located between the second semiconductor device and the carrier;
wherein, in a cross-sectional view, the first adhesive portion comprises an inclined sidewall, and the inclined sidewall is adjacent to the carrier and forms an interior angle greater than 90 degrees to the carrier.

2. The semiconductor device arrangement according to claim 1, wherein the first semiconductor device arrangement comprises a plurality of depression areas having repetitive shapes, facing the carrier, and being filled with the first adhesive portion.

3. The semiconductor device arrangement according to claim 1, wherein the first adhesive portion and the second adhesive portion include a patterned photoresist layer.

4. The semiconductor device arrangement according to claim 1, wherein the adhesive portion further comprises a lower surface contacting the carrier, in a top view, a projection area of the lower surface is smaller than a projection area of the first semiconductor device.

5. The semiconductor device arrangement according to claim 1, wherein the first adhesive portion further comprises a protruding portion, a top portion, and a bottom portion, and the protruding portion is located between the top portion and the bottom portion.

6. The semiconductor device arrangement according to claim 1, wherein the carrier is electrically insulated from the first semiconductor device.

7. The semiconductor device arrangement according to claim 1, wherein a projection area of the first semiconductor device is 50 μm² to 5000 μm².

8. The semiconductor device arrangement according to claim 1, wherein the first semiconductor device and the second semiconductor device are adjacent to each other and there is a minimum distance from 1 μm to 50 μm therebetween.

9. The semiconductor device arrangement according to claim 1, wherein the first semiconductor device comprises an electrode facing the carrier and separated from the carrier by the first adhesive portion.

10. A method of manufacturing a semiconductor device arrangement, comprising:
providing a first supporting substrate, a first semiconductor device, and a second semiconductor device, wherein the first semiconductor device and the second semiconductor device are located on the first supporting substrate and separated from each other;
providing a patternable adhesive layer to cover the first semiconductor device, the second semiconductor device, and a space between the first semiconductor device and the second semiconductor device;
removing the patternable adhesive layer located in the space by a photolithographic process to form a first adhesive portion and a second adhesive portion; and
providing a second supporting substrate and contacting the first adhesive portion and the second adhesive portion to the second supporting substrate;
wherein the first adhesive portion is located between the first semiconductor device and the second supporting substrate and the second adhesive portion is located between the second semiconductor device and the second supporting substrate.

11. The method according to claim 10, further comprising separating the first supporting substrate and the second supporting substrate.

12. The method according to claim 10, wherein the first supporting substrate comprises a growth substrate, and the first semiconductor device and the second semiconductor device are formed on the growth substrate.

13. The method according to claim 10, wherein the patternable adhesive layer fully fills the space.

14. The method according to claim 10, further comprising proceeding a photolithographic process to expose a portion surface of the first supporting substrate.

15. The method according to claim 10, wherein the patternable adhesive layer fully covers the first semiconductor device and the second semiconductor device.

16. The method according to claim 10, wherein the first semiconductor device comprises a plurality of outermost sidewalls, and after the removing step, more than 50% of the area of the plurality of outermost sidewalls is not covered by the first adhesive portion.

17. The method according to claim 10, wherein in a top view, the first adhesive portion and the first semiconductor are overlapped.
